(19) United States
(12) Patent Application Publication
(10) Pub. No.: US 2023/0213870 A1
(43) Pub. Date: Jul. 6, 2023

(54) METROLOGY METHOD AND SYSTEM FOR CRITICAL DIMENSIONS BASED ON DISPERSION RELATION IN MOMENTUM SPACE

(71) Applicants: Fudan University, Shanghai (CN); Shanghai Ideaoptics Corp., Ltd., Shanghai (CN)

(72) Inventors: Tongyu Li, Shanghai (CN); Lei Shi, Shanghai (CN); Ang Chen, Shanghai (CN); Guopeng Lu, Shanghai (CN); Haiwei Yin, Shanghai (CN); Jian Zi, Shanghai (CN)

(21) Appl. No.: 17/927,974

(22) PCT Filed: Aug. 12, 2020
(86) PCT No.: PCT/CN2020/108604

§ 371 Date: Nov. 28, 2022

(30) Foreign Application Priority Data
May 29, 2020 (CN) 202010474340.3

(51) Int. Cl. G03F 7/20; G01N 21/95; G01B 11/02

(52) U.S. Cl. CPC G03F 7/70625; G01N 21/9501; G01B 11/02; G01B 2210/56

(57) ABSTRACT

Embodiments of the present disclosure relate to a metrology method and system for critical dimensions based on a dispersion relation in momentum space. The method comprises: establishing, in accordance with parameters of incident light and a modeled geometric topography of the target to be measured, a simulation dataset associated with a dispersion curve of the target to be measured in momentum space; training a neural-network-based prediction model based on the simulation dataset; obtaining, based on an actual measurement of the target to be measured by incident light, a dispersion relation pattern of the target to be measured in momentum space, wherein the dispersion relation pattern at least indicates a dispersion curve associated with the critical dimensions of the target to be measured; extracting, based on the dispersion relation pattern, features related to the dispersion curve from the dispersion relation pattern via the trained prediction model, to determine an estimated value associated with at least one critical dimension of the target to be measured. According to the method disclosed herein, at least one critical dimension is measured in a more efficient, economical and accurate way.

### FIELD

Various embodiments of the present disclosure relate to the metrology field, and more specifically to a metrology method, system, computing device and storage medium for determining critical dimensions of a target to be measured.

### BACKGROUND

Optical Critical Dimension (OCD) measurement is an important task in the existing micro-nano manufacturing of semiconductors.

With micro-nano technologies more extensively applied into the semiconductor industry, the dimension of the integrated circuit devices continues to downsize, but structure design of such devices becomes more complicated. The emergence of the three-dimensional devices, in particular, gives more weight to the process control in the manufacturing of semiconductors. During production, only with a strict control process, the fully functional circuits and devices operating at a high speed can be obtained. In such case, the method for accurately and efficiently measuring the optical critical dimensions becomes a challenge.

The traditional methods for measuring the critical dimensions, for example, may be performed based on a diffraction spectrum (or reflection spectrum) of the target to be measured, wherein the diffraction spectrum (or reflection spectrum) may vary with the wavelength, diffraction angle and/or polarization. The critical dimensions are then determined by conducting a spectrum comparison with a library search.

### SUMMARY

The present disclosure proposes a new metrology method for critical dimensions, which may be applied to detecting the micro-nano manufacturing and measuring the critical dimensions in a more efficient, accurate and economical way.

According to a first aspect of the present disclosure, there is provided a metrology method for determining critical dimensions of a target to be measured. The method comprises: establishing, in accordance with parameters of incident light and a modeled geometric topography of the target to be measured, a simulation dataset associated with a dispersion curve of the target to be measured in momentum space, wherein the modeled geometric topography is characterized by a plurality of critical dimensions; training a neural-network-based prediction model based on the simulation dataset; obtaining, based on an actual measurement of the target to be measured by incident light, a dispersion relation pattern of the target to be measured in momentum space, wherein the dispersion relation pattern at least indicates a dispersion curve associated with the critical dimensions of the target to be measured; and extracting, based on a dispersion relation pattern, features related to the dispersion curve from the dispersion relation pattern via the trained prediction model, to determine an estimated value associated with at least one critical dimension of the target to be measured.

The method of the present disclosure first proposes estimating values of the critical dimensions using the dispersion relation pattern in momentum space and efficiently determining at least one critical dimension of the target to be measured via a trained neural-network-based prediction model. The dispersion relation pattern in momentum space contains rich information regarding the incident light and the structure of the target to be measured. Accordingly, if the optical critical dimensions of the target to be measured are to be measured based on the dispersion relation pattern, the measurement accuracy can be advantageously enhanced. In addition, the optical critical dimensions of the target to be measured with a relatively complicated structure can also be measured. When the optical critical dimensions of the target to be measured are measured based on the extracted features related to the dispersion curves via the trained neural-network-based prediction model, the computation mainly involves matrix multiplication and stores network parameters and network structures with a small data scale. Compared to traditional metrology methods for measuring critical dimensions which depend on the diffraction spectrum and library search comparison, the present disclosure is more transportable and can more quickly compute the critical dimensions. Therefore, the technical solution according to the present disclosure is a new technical path to micro-nano structure measurement and is completely different from the spectrum comparison and library search principle in the prior art. The method according to the present disclosure may obtain critical dimensions of the target to be measured in a more efficient, accurate and economical way.

In some embodiments, extracting features related to the dispersion curve from the dispersion relation pattern via the trained prediction model, to determine an estimated value associated with at least one critical dimension of the target to be measured includes: outputting via the neural network an estimated probability density distribution of the at least one critical dimension. In these embodiments, the estimated probability density distribution may be applied to measure the critical dimension value with a precision sufficient for measurement of semiconductors. In some embodiments, the prediction model may be a regression model of the neural network.

In some embodiments, obtaining, based on an actual measurement of the target to be measured by incident light, a dispersion relation pattern of the target to be measured in momentum space includes: measuring the target to be measured in practice with at least one of s-polarized light and p-polarized light, to obtain at least one of corresponding s-polarized and p-polarized dispersion relation patterns of the target to be measured in momentum space. In further embodiments, the s-polarized and p-polarized dispersion relation patterns may be simultaneously input to the neural network in a single computation for determining the critical dimensions, to obtain an estimated value associated with at least one critical dimension of the target to be measured. In such a way for obtaining the dispersion relation pattern, the feature values of dispersion curves in the dispersion relation pattern may be more accurately extracted.

Although the s-polarized light and the p-polarized light are used here, the technical solution of the present disclosure is not limited to the s-polarized light and the p-polarized light as incident light. Natural light, circularly polarized or elliptically polarized lights may also be incident light in some other embodiments.

In some embodiments, obtaining the simulation dataset includes obtaining the simulation dataset by altering one or more of: incidence angle of incident light; wavelength of incident light; polarization of incident light; and critical dimensions of the modeled geometric topography. In this way, a large scale of the simulation dataset may be obtained and the significant time costs for actual measurements and data collection can be avoided.

In some embodiments, the method also may comprise adding noises related to light intensity into at least a part of the simulation dataset, to obtain an enhanced simulation dataset that simulates potential measurement noises; and training the prediction model based on the enhanced simulation dataset. Accordingly, the robustness to light intensity interference may be obtained and the critical dimensions are measured more accurately. As an example, the above noises related to light intensity may include one or more of a low-frequency disturbance, a Gaussian noise, a Perlin noise or a Gaussian function type disturbance.

In some embodiments, the target to be measured may be measured in practice with an angle-resolved spectrometer, and the dispersion relation pattern of the target to be measured in momentum space is obtained by way of photo-shooting or scanning. Therefore, the dispersion relation pattern in momentum space may be easily obtained as a picture.

In some embodiments, the angle-resolved spectrometer has a measurement angle selected from a range from −60 to 60 degrees and a measuring wavelength selected from an near-infrared band from 900 nm to 1700 nm, or a visible light band from 360 nm to 900 nm, or an ultraviolet band from 200 nm to 360 nm. In this way, the measurement may be carried out within wide angles and broad wavelength range.

In some embodiments, obtaining a dispersion relation pattern of the target to be measured in momentum space may include: obtaining the dispersion relation pattern of the target to be measured in momentum space under the incident light on the basis of a dispersion relation pattern of the background of the target to be measured in momentum space and a dispersion relation pattern of a light source of the incident light in momentum space.

In some embodiments, both the dispersion curve and the dispersion relation pattern are defined by a first coordinate and a second coordinate, wherein the first coordinate denotes energy or wavelength and the second coordinate denotes angle or momentum. It is to be understood that the conversion between the energy and the wavelength and between the angle and the momentum may be carried out easily via a known formula. Therefore, in momentum space, the energy and the wavelength may be used interchangeably. This also applies to the angle and the momentum.

In some embodiments, the method may also comprise: adjusting the metrology system according to Abbe sine conditions, to eliminate aberrations in imaging results.

In some embodiments, the method may also comprise: correcting the simulation dataset via at least one of an angular resolution correction and a numerical aperture correction for a measuring objective lens. In this way, a more accurate simulation dataset may be obtained.

In some embodiments, obtaining the simulation dataset includes: establishing the simulation dataset based on at least one of Rigorous Coupled Wave Analysis (RCWA) algorithm, Finite Difference Time Domain (FDTD), Finite Element Method (FEM) and Boundary Element Method (BEM).

In some embodiments, the neural network is a convolutional neural network. Furthermore, the convolutional neural network may be a neural network consisting of three convolutional layers and three fully connected layers.

According to a second aspect of the present disclosure, there is provided a metrology method for determining critical dimensions of a target to be measured. The method comprises: obtaining a dispersion relation pattern of the target to be measured in momentum space, wherein the dispersion relation pattern is generated in momentum space via a spectrum apparatus after the target to be measured is illuminated by incident light and the dispersion relation pattern at least indicates a dispersion curve related to critical dimensions of the target to be measured; extracting, based on the dispersion relation pattern, features related to the dispersion curve from the dispersion relation pattern via a neural-network-based prediction model; and determining, based on extracted features related to the dispersion curve, an estimated value associated with at least one critical dimension of the target to be measured.

In some embodiments, the prediction model has been trained using a simulation dataset established on the basis of parameters of incident light and a modeled geometric topography of the target to be measured, wherein the modeled geometric topography is characterized by a plurality of critical dimensions of a target to be measured.

According to a third aspect of the present disclosure, there is provided a metrology system. The metrology system is configured to comprise a spectrometer configured to generate, based on an actual measurement of the target to be measured by incident light, a dispersion relation pattern of a target to be measured in momentum space, wherein the dispersion relation pattern at least indicates a dispersion curve related to critical dimensions of the target to be measured; and a computing device configured to operatively execute the metrology method according to any embodiments in the first aspect.

According to a fourth aspect of the present disclosure, there is provided a computing device. The computing device comprises: a memory configured to store one or more computer programs; and a processor coupled to the memory and configured to execute the one or more programs, enabling a metrology apparatus or a metrology system to perform the metrology method according to any of the first and second aspects.

According to a fifth aspect of the present disclosure, there is provided a non-transient machine-readable storage medium with machine-readable program instructions stored thereon, wherein the machine-readable program instructions may be configured to enable a metrology apparatus or a metrology system to perform the method in accordance with the embodiments of the first and second aspects.

It is to be appreciated that although the above various aspects of the present disclosure have described measuring or obtaining the critical dimensions of the target to be measured using a neural-network-based prediction model in combination with the dispersion relation pattern, it is also possible to obtain the critical dimensions of the target to be measured by using the traditional spectrum comparison or a library search in combination with the dispersion relation pattern.

Therefore, in some embodiments, a metrology method for determining critical dimensions of a target to be measured may include: obtaining a dispersion relation pattern of the target to be measured in momentum space, wherein the dispersion relation pattern is generated in momentum space via a spectrum apparatus after the target to be measured is illuminated by incident light and at least indicates a dispersion curve related to critical dimensions of the target to be measured; and one of the following steps: determining, based on the dispersion relation pattern and spectrum comparison or a library search, an estimated value related to critical dimensions of the target to be measured; or extracting, based on the dispersion relation pattern and spectrum comparison or a library search, a feature value related to critical dimensions of the target to be measured, and then determining the estimated value related to critical dimensions of the target to be measured from the feature value.

It is to be understood that contents described in the Summary are not intended to restrict key or important features of the embodiments of the present disclosure, or limit the scope of the present disclosure. Other features of the embodiments of the present disclosure will be easily understood through the following description.

### BRIEF DESCRIPTION OF THE DRAWINGS

Through the following detailed description with reference to the accompanying drawings, the above and other features, advantages and aspects of various embodiments of the present disclosure will become more apparent. Throughout the drawings, same or similar reference signs may represent same or similar elements, wherein:

FIG. 1 illustrates a schematic diagram of a system for implementing a metrology method for determining critical dimensions of a target to be measured in accordance with embodiments of the present disclosure;

FIG. 2 illustrates a schematic diagram of a section of a grating model built in accordance with one embodiment of the present disclosure;

FIG. 3 illustrates a schematic structural diagram of a reflective angle-resolved spectrometer in accordance with one embodiment of the present disclosure;

FIG. 4 illustrates a schematic diagram of all-ray reception in accordance with one embodiment of the present disclosure;

FIG. 5 illustrates an example of a neural network architecture in deep leaning in accordance with one embodiment of the present disclosure;

FIGS. 6a to 6d illustrate comparative examples between experimental results and those results obtained from a metrology method for critical dimensions in accordance with one embodiment of the present disclosure;

FIG. 7 illustrates a flowchart for determining at least one critical dimension of the target to be measured in accordance with one embodiment of the present disclosure; and

FIG. 8 schematically illustrates a block diagram of an electronic device adapted to implement embodiments of the present disclosure.

### DETAILED DESCRIPTION OF EMBODIMENTS

Embodiments of the present disclosure will be described in more details with reference to the drawings. Although the drawings illustrate some embodiments of the present disclosure, it should be appreciated that the present disclosure can be implemented in various manners and should not be limited to the embodiments explained herein. On the contrary, the embodiments are provided to understand the present disclosure more thoroughly and completely. It is to be understood that the drawings and the embodiments of the present disclosure are provided only as examples, rather than limiting the protection scope of the present disclosure.

As stated in the Background Art, during the manufacturing of the large-scale integrated circuits, a metrology procedure is simultaneously carried out. One of the most common approaches for measuring the manufacturing process (e.g., etching process) is to measure the geometric topography of a target to be measured (such as an etched grating). Herein, the present disclosure proposes a new method for measuring critical dimensions of the target to be measured, i.e., measuring at least one critical dimension of the target by identifying characteristics of a dispersion curve of the target to be measured in momentum space.

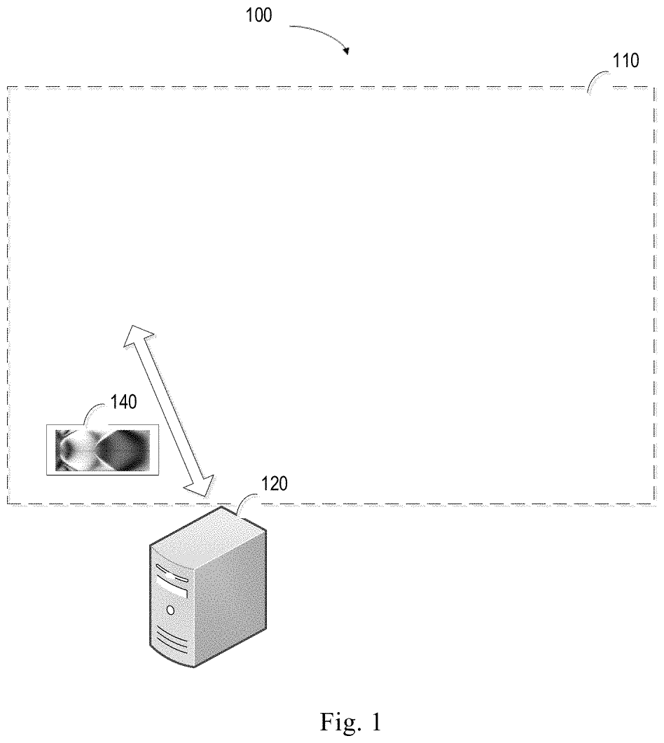

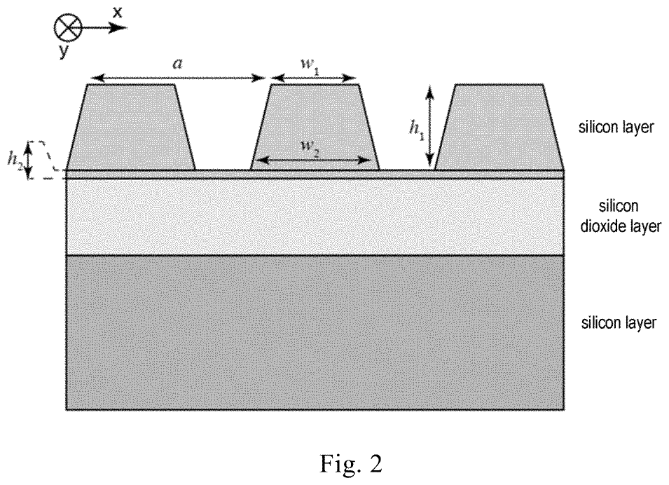

FIG. 1 illustrates a schematic diagram of an example system for implementing a metrology method for determining critical dimensions of the target to be measured in accordance with embodiments of the present disclosure. As shown in FIG. 1, the system 100 may include a spectrum measuring device 110, a computing device 120 and a target to be measured 130. As an example, the target to be measured 130 for example is an etched grating as illustrated below in FIG. 2.

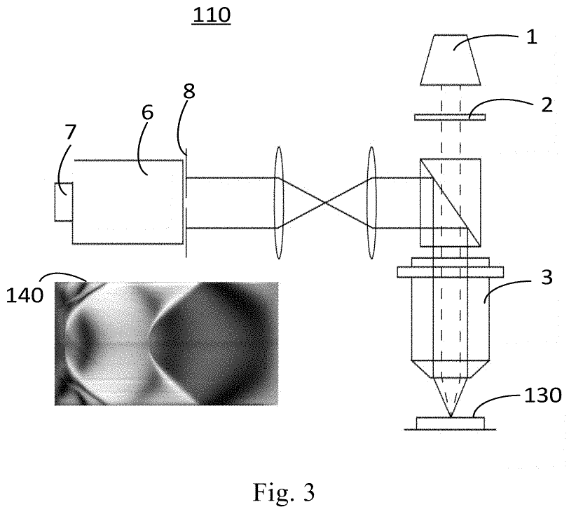

The spectrum measuring device 110, for example, may be an angle-resolved spectrometer, especially a reflective angle-resolved spectrometer. The spectrum measuring device 110 may generate, based on an actual measurement of the target to be measured 130 under incident light, a dispersion relation pattern 140 in momentum space, where the dispersion relation pattern 140 at least indicates a dispersion curve associated with critical dimensions of the target to be measured 130. The spectrum measuring device 110 will be described in details below with reference to FIG. 3.

The computing device 120 may determine at least one critical dimension of the target to be measured based on a trained prediction model and the dispersion relation pattern. A plurality of samples for training the prediction model may be acquired from a sample dataset established on the basis of a plurality of sample dispersion relation patterns experimentally measured for the target to be measured in momentum space under the incident light, or from a simulation dataset established through a simulation approach regarding the dispersion curve of the target to be measured in momentum space. For example, the computing device 120 may establish a simulation dataset related to the dispersion curve of the target to be measured in momentum space based on the parameters of the incident light and the geometric topography model of the target to be measured.

It is to be understood that the experiment-based dispersion curve sample dataset can reflect the true condition of the experiment equipment. On the basis of the simulation dataset established via a numerical simulation approach, a large scale of training dataset can be obtained in a highly efficient way, which further enhances the efficiency in training the prediction model and also lowers the costs of such training. In some embodiments, the computing device 120, for example, may be a server. In some other embodiments, the computing device 120 may be provided with one or more processing units, such as dedicated processing units including GPU, FPGA and ASIC etc. and general processing units like CPU. In addition, one or more virtual machines may also be running on each computing device.

It should be noted that although the spectrum measuring device 110 and the computing device 120 are illustrated above as discrete components, the spectrum measuring device 110 and the computing device 120 may also be integrated into a single component in some embodiments.

During the semiconductor etching process in practice, it is often impossible to shape the cross-section of the target to be measured (such as etched grating) into an ideal rectangle. For this, the present disclosure proposes a suitable model and describes the geometric topography of the target with a plurality of parameters.

Just as an example of the target to be measured 130, FIG. 2 depicts an etched grating as a model of the target, wherein the etched grating has a cross-sectional shape of an isosceles trapezoid. The structure of the grating may be described by four critical dimensions, including upper base w₁, lower base w₂ and height h₁ of the trapezoid, and period a for the grating. It is to be explained that the four critical dimensions are just shown as an example. For the geometric topography of a grating, other critical dimensions may also be included, e.g., inclination angle of sidewalls, etc. Example implementations of the method in accordance with the present disclosure will be elaborated below from the perspective of experiments and algorithm, respectively.

1. Experiment Part

1.1 Measurement Based on Angle-Resolved Spectrometer

As an example only, the dispersion curve of the target may be measured using an angle-resolved spectrometer (e.g., a reflective angle-resolved spectrometer).

FIG. 3 illustrates a schematic structure of a spectrum measuring device 110 (such as a reflective angle-resolved spectrometer).

The reflective angle-resolved spectrometer relates to a type of spectral imaging technology in momentum space based on the Fourier optics method. As shown in FIG. 3, the reflective angle-resolved spectrometer mainly includes an imaging optical part and a spectrum analysis part.

In the imaging optical part, light (e.g., natural light) is converged by an illumination source 1 via a polarizer 2 and an objective lens 3 and then incident upon the surface of the target to be measured 130. The reflected light of the target to be measured passes through the objective lens 3 again to produce a Fourier image of the target to be measured 130 at a back focal plane of the objective lens 3. The Fourier image at the back focal plane of the objective lens is then imaged to the spectrum analysis part by the rest imaging part.

The spectrum analysis part may mainly consist of a spectrometer 6, an imager 7 (e.g., 2D CCD array) and a slit 8. The slit 8 is provided for selecting momentum coordinates on the Fourier image of the target to be measured that requires spectrum analysis. For the Fourier image (or known as a reciprocal space image or momentum space image), the momentum coordinates can be represented by e.g., kx and ky and may be unfolded at any ky. Assuming it is required to unfold at ky=0, the slit 8 may be switched to its minimum width and aligned to a straight line position corresponding to the Fourier image at ky=0, to filter the momentum coordinates to be input to the spectrometer. A linear Fourier image, which is filtered to be input to the spectrometer, will be unfolded according to wavelength into a two-dimensional image imaged on an imager such as 2D CCD array.

Just as an example, the above light source, objective lens and spectrometer may be provided as below:

Objective lens: MplanFLN 100X@Olympus; illumination source: U-LH100L-3@Olympus; spectrometer: HRS-300@Princeton Instrument; CCD: PIXIS:1024@Princeton Instrument. Besides, a silver mirror (ME05S-P01@Thorlabs) may also be provided as an auxiliary device.

For an etched grating sample to be measured, it is assumed in some embodiments that a direction of the periodical change of the grating is kx direction and the groove direction of the grating is ky direction. The dispersion relation pattern in momentum space is accordingly measured at the predetermined ky. The dispersion relation pattern is formed with a dispersion curve therein reflecting critical dimensions of the target to be measured. The dispersion curve optically represents a trajectory of changes of eigenvalues of an optical eigen equation in momentum space. Just as an example, the dispersion relation pattern of the grating sample to be measured may be measured along the ky=0 direction in momentum space when being illuminated by s- and p-polarized light.

In some embodiments, the range of wavelength for imaging in momentum space may be configured by the spectrometer. For example, it may be configured within a desired range of the measurement angle and the wavelength. For instance, the spectrometer may be provided with a measurement angle ranging e.g., from −55 to 55 degrees and a near-infrared band e.g., from 900 nm to 1700 nm, or a visible light band e.g., from 400 to 900 nm, or an ultraviolet band e.g., from 200 to 360 nm.

In case of a relatively wide band range (such as a near-infrared band from 900 nm to 1700 nm), the spectrum may be measured by bands and then spliced together. For example, the wavelength range may be divided into a plurality of portions for individual measurements (e.g., three measurements). In each measurement, a plurality of results (e.g., 20 results) may be recorded and subsequently averaged before the spectrum splicing.

In some embodiments, in order to obtain the dispersion relation pattern of a target to be measured in momentum space, at least one of the s-polarized light or the p-polarized light may be selected as the incident light. However, this is not compulsory and in some other embodiments other linearly polarized, circularly polarized or elliptically polarized lights may also be incident light.

In order to increase the accuracy of the obtained dispersion relation pattern of the target to be measured in momentum space, in some embodiments, it may be required to consider the effects of the dispersion relation pattern of the background of the target to be measured in momentum space as well as the dispersion relation pattern of the light source in momentum space itself on the dispersion relation pattern of the target to be measured in momentum space. Accordingly, the dispersion relation pattern I_{background,m} of the background of the target to be measured in momentum space, the dispersion relation pattern I_{source,m} of the light source in momentum space and the actually measured initial dispersion relation pattern I_{sample,m} of the target to be measured in momentum space may be measured in sequence. With the above factors taken into account, the dispersion relation pattern Iₛₐₘₚₗₑ of the target to be measured in momentum space may be then calculated as below:

$${I}_{sample} = \frac{{I}_{sample , m} - {I}_{background , m}}{{I}_{source , m} - {I}_{background , m}} \qquad ( 1 )$$

As an example, a momentum space image (i.e., the dispersion relation pattern) of the background, i.e., I_{background,m} may first be obtained when an object stage is empty. The silver mirror may then be placed on the object stage and used to measure a momentum space image I_{source,m} of the light source (Note: When measured with the silver mirror, the objective lens should be focused on the surface of the silver mirror and an aperture may be provided as an aid). A target to be measured may finally be placed and measured to obtain a momentum space image i_{sample,m} (Note: The surface of the target needs to be adjusted to a horizontal level, its grating direction to be aligned along ky=0 and the objective lens to be focused on the sample surface). Thereafter, according to the above equation (1), the dispersion relation pattern Iₛₐₘₚₗₑ of the target to be measured in momentum space when illuminated by incident light (e.g., polarized light) can then be obtained.

In some embodiments, the above measured background may be a dark background, i.e., having merely background signals received by the detector in case of no input signals.

Note: The effects of the dispersion relation pattern of the background in momentum space and the dispersion relation pattern of the light source in momentum space are both considered in the form of equation (1) in the above embodiments. However, it should be understood that the equation (1) is just an example and in other embodiments the effects of the above two factors may also be revised in other equations different from the equation (1).

In some embodiments, for a plurality of samples to be measured, the background and the light source could be measured only once. However, if the polarization of the incident light is changed, the background and the light source need to be measured again due to the effect of the polarizer. In some other embodiments, no changes need to be made to the measurement system if the polarizer is not provided or kept fixed.

In some embodiments, in order to obtain the dispersion relation pattern of the target to be measured in momentum space under the incident light, a sum of the dispersion relation pattern of the background of the target to be measured in momentum space and the dispersion relation of the light source of the incident light in momentum space may be used by the computing device 120 to acquire a more accurate dispersion relation pattern of the target to be measured in momentum space under the incident light.

It should be appreciated that with different structures or dimensions of the target to be measured, the corresponding dispersion relation patterns of the target to be measured in momentum space under the incident light may also be different. The optical critical dimensions of the target to be measured may be measured on the basis of the measured dispersion relation patterns.

1.2 Processing of Measurement Results

In some embodiments, the measured dispersion curves of the grating samples are converted into measurement results in momentum-wavelength or angle-wavelength coordinates according to the momentum-angle conversion equation under the Abbe sine condition.

In some embodiments, the measured dispersion curves of the targets to be measured may undergo the smoothing and downsampling processes prior to being input to a neural network.

Just as an example, assuming that the image pixel resulted from spectrum splicing is e.g., 512×1944, the measured dispersion image may be smoothed using a 10×10 Gaussian convolutional kernel. Subsequent to the above correction, on the assumption that the angular coordinates are measured to be in the range from −55 to 55 degrees and the wavelength in the range from 900 nm to 1700 nm, data within a range from 0 to 50° may be selected. The image pixels may be downsampled to 51×267 by taking values at a regular interval and then the downsampled image may serve as an input image for the neural network.

2. Algorithm Part

As stated above, the present disclosure proposes an approach of obtaining the critical dimensions of the target to be measured by using a neural network.

2.1 Establishment of Dataset

It is to be understood that the training of the neural network depends on a large-scaled dataset. In some embodiments, the dataset of the dispersion curve for the modeled geometric topography of the target to be measured (e.g., grating sample) may be established based on a plurality of experiments.

However, to obtain the dataset of the grating dispersion curve based on the experiments might require preparation of expensive samples, massive angle resolution measurements and calibrations for the critical dimensions of the modeled geometric topography of the respective targets to be measured. For a dataset containing thousands of samples, although the dispersion curve dataset based on the experiments can more truthfully reflect the conditions of the experiment equipment, it still disadvantageously costs too much and consumes a large amount of time.

In some embodiments, as an alternative, a simulation dataset may be established via a numerical simulation method. In some embodiments, according to the considerations for computational accuracy and operational efficiency, a Rigorous Coupled Wave Analysis (RCWA) algorithm may be employed to simulate the measurement results of the grating samples by the angle-resolved spectrometer. It is to be understood that the Rigorous Coupled Wave Analysis (RCWA) algorithm is just an example. In other embodiments, other suitable algorithms (such as Finite Difference Time Domain (FDTD), Finite Element Method (FEM) and Boundary Element Method (BEM)) and/or combinations thereof may also be utilized to simulate the measurement results of the grating samples by the angle-resolved spectrometer.

Since it is impossible to etch a grating with a perfect rectangular section in practice, the geometric topography (e.g., grating structure) of the target to be measured may be modeled into a trapezoid. The grating structure may be described using at least four critical dimensions: upper base w₁, lower base w₂ and height h₁ of the trapezoid, and period a of the grating, as illustrated in FIG. 1. It is to be understood that it is not necessary to model the grating structure in the shape of a trapezoid in all cases. In other examples, the grating structure may be modeled into other shapes as desired. Besides, more critical dimensions may also be required.

In the practical fabrication of the gratings, top silicon of an SOI silicon wafer may be etched by argon and a grating structure having parameters different from the above demonstrated ones may be etched on the top silicon, wherein parameters of the SOI silicon wafer may be regarded as known parameters, including the thickness of the top silicon layer, the silicon dioxide layer and the bottom silicon layer and the real and imaginary parts of the dielectric constant.

Therefore, in some embodiments, the simulation dataset may be built by altering the above at least four critical dimensions of the modeled geometric topography (e.g., grating structure) of the target to be measured within a range of priori parameters.

Just as an example, during the preparation of the simulation dataset, the period of the grating may be selected in a range from 350 nm to 550 nm; the upper base of the grating may be selected in a range from 100 nm to 250 nm; the height of the trapezoid may be selected in a range from 150 nm to 260 nm; the inclination angle of the sloping side of the trapezoid may be selected in a range from 0 to 45°. The range for the lower base of the trapezoid may then be calculated accordingly. As the bottom silicon of the SOI silicon wafer has a thickness (of about 500 micrometers) much greater than the wavelength of the incident light and the bottom surface of the SOI is frosted, the SOI bottom silicon may serve as a substrate with an infinite thickness in the simulation. Without compromising the precision, when using the RCWA algorithm, the Fourier series may be kept to e.g., 13th order in the simulation. To obtain a grating structure similar to, e.g., a trapezoidal grating structure etched on the top silicon in the model, the trapezoidal grating structure may be uniformly divided into 13 layers of rectangles aligned with respect to a symmetrical axis and having incremental widths. In the example embodiment of the angle-resolved spectrometer that detects the near-infrared bands, a reception angle of the objective lens may be in a range from −55 to +55 degrees, the detectable wavelength may be in a range from 900 nm to 1700 nm, and the polarization of the incident light may be adjusted freely.

In some embodiments, during the simulation, the incident angle may be altered by a predetermined angle interval, and/or the wavelength of the incident light may be altered by a predetermined wavelength interval, and/or the polarization of the incident light may be altered, so as to obtain the simulation dataset. As an example, the incident angle may be altered by an interval of 1 degree within the range from 0 to 50 degrees; the wavelength of the incident light may be altered by an interval of 3 nm within the range from 900 nm to 1700 nm; or the incident light may be selected to be s-polarized light or p-polarized light respectively. In the end, the measurement results of the angle-resolved spectrometer may be simulated with angle or momentum as the horizontal coordinate and wavelength or energy as the vertical coordinate.

In the practical measurement, the numerical aperture of the measuring objective lens also influences the measured dispersion relation pattern. As such, the correction for the finite acceptance angle of the objective lens should also be considered in the RCWA simulation. Moreover, the RCWA algorithm could not directly perform an all-ray simulation. The so-called “all-ray” here refers to a scenario where the natural light is incident from all angles. Therefore, in some embodiments it is required to correct the simulation dataset obtained by the RCWA algorithm.

In some embodiments, the simulation dataset may be corrected by introducing corrections for angular resolution and/or numerical aperture of the measuring objective lens.

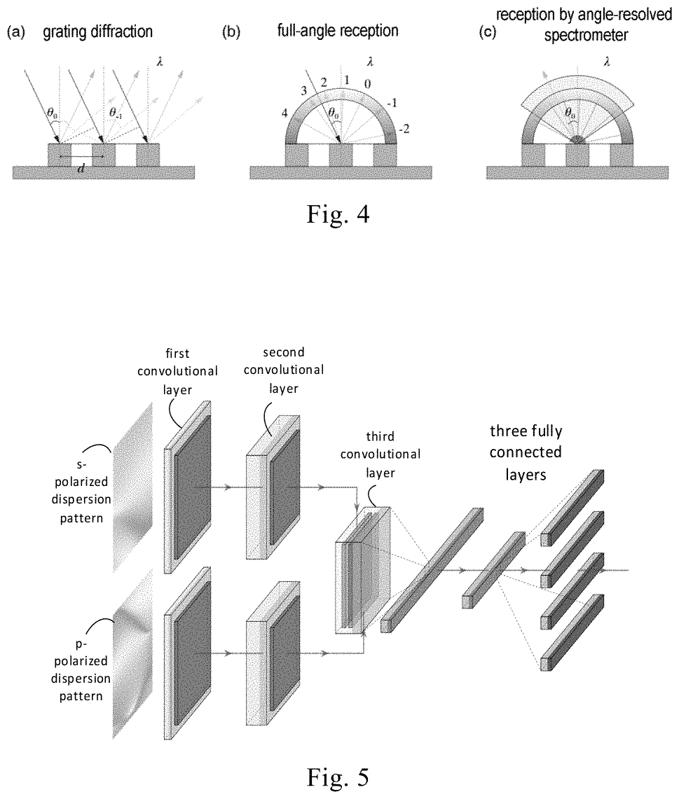

FIG. 4 illustrates a schematic diagram of all-ray reception. As an example, in the embodiment in which the reflective angle-resolved spectrometer is in an all-ray measurement mode, light having different wavelengths and different horizontal wave vectors k_{//} are simultaneously incident upon a target to be measured from the objective lens. The reflected light of the target to be measured is received again by the objective lens. The dispersion relation pattern of the target to be measured is obtained through Fourier transform of the objective lens and beam splitting of the spectrometer.

2.2 Neural Network Algorithm

The present disclosure proposes to extract information from the measured dispersion curve of the target to be measured by using a neural network, so as to measure the critical dimensions of the target to be measured (e.g., grating).

In some embodiments, the robustness of the measurement of optical critical dimensions of the target (e.g., grating) may be realized by using the neural network algorithm of the deep learning.

2.2.1 Architecture of Neural Network

As an example, a convolutional neural network consisting of three convolutional layers and three fully connected layers may be built. FIG. 5 illustrates an example of the architecture of the neural network of the deep learning. In the example shown in FIG. 5, the s-polarization and p-polarization measurement results (dispersion curves) may be respectively input to the neural network from two branches of the convolutional layer. The s- and p-polarized dispersion curves are each passed through two respective convolutional layers so as to extract a feature map. Subsequent to the feature extraction in each convolutional layer, the features are further extracted with Max-pooling. The feature maps extracted from the previous two layers are combined and then passed through a third convolutional layer so as to extract the feature again.

As a further example, the first convolutional layer may use a convolution kernel, e.g., of 5×5, to extract 24 feature maps from the input dispersion curve profile; the second convolutional layer may use a convolution kernel, e.g., of 5×5, to continue extracting 32 feature maps from the output feature map of the first layer; and the third convolutional layer may use a convolution kernel, e.g., of 3×3, to extract 64 feature maps from the combined feature maps from the two branches. Finally, the extracted feature maps are input to a fully-connected neural network to measure the critical dimensions of the target to be measured, wherein the neuron quantity of the three fully-connected layers of the neural network may be 2 million, 400,000 and 330,000, respectively.

In some embodiments, the output of the neural network may be vectors having the same number as the parameters to be measured and each vector represents a score for discrete probability density distribution of the critical dimension within the priori range.

Since the critical dimensions to be measured are all parameters of geometric length, the priori range of the parameter in some other embodiments may be discretized by a predetermined interval. As an example, the discretization may be performed by an interval of 1 nm and each element in the vector corresponds to one dimension value. For example, if the periodicity parameter of the target to be measured (e.g., grating) has a priori range from 350 nm to 550 nm, the neural network output vector corresponding to the grating period may include 201 elements and each element corresponds to one value between 350 nm and 550 nm. Therefore, in some embodiments, a value of a given element on the output vector indicates a score of a corresponding parameter value of the critical dimension to be measured at this point.

In some embodiments, the estimated probability density distribution in discrete form for respective critical dimensions within the priori parameter range can be obtained based on the score vector of each parameter. As an example, the score vector of each parameter may be processed by a softmax function to obtain the above estimated probability density distribution in discrete form.

2.2.2 Training of Neural Network

As stated above, it is required to train the neural network on a dataset. In some embodiments, the dataset may include any one of above mentioned simulation dataset, the sample dataset acquired from experiments, or a combination thereof.

Particularly, in some embodiments, the neural network may be trained only on the above simulation dataset. As an example, by means of the above method for the simulation dataset, 25,000 modeled geometric topography (e.g., trapezoidal SOI grating sample) with distinct geometric parameters for the targets to be measured may be generated, wherein 90% of the simulation dataset may serve as the training set for the neural network and the rest 10% may serve as a test set for testing the training condition of the network.

In some embodiments, a training task of the neural network may be transformed as minimizing a loss function, where the loss function C may be expressed as:

$$\text{?} \qquad ( 6 )$$

$$\text{?} \text{indicates text missing or illegible when filed}$$

In the above equation (6), a cross entropy function is used to describe the degree of difference between the probability density distribution p and distribution δ(x-g) of the parameters to be measured output from the neural network, and averaging is performed on the dataset. In the equation (6), Rin is an input dispersion relation graph, z represents output of the neural network, θ indicates a network parameter, m is the quantity of samples in the dataset, q is the number of critical dimensions to be measured, n denotes discrete number of the probability distribution output by the network, g represents label of the dataset, and r is a dimension value corresponding to the vector element output by each elemental neural network. In some embodiments, it may be empirically assumed that the probability density distribution of the parameter is non-zero only within a certain range, which range may be determined by the manufacturing method and the experimental experience and is an interval much wider than the manufacturing error range.

The object of training is to optimize the differences between the predicted value and the correct value of the critical dimensions by iteratively updating the respective parameters θ of the neural network. The optimization procedure may be described as:

$$\text{?} \qquad ( 7 )$$

$$\text{?} \text{indicates text missing or illegible when filed}$$

wherein θ is a network parameter including the convolution kernel in the neural network. In the example of the fully connected layers, θ consists of the weight and bias of the fully connected layers; and wherein C is the loss function, g indicates a label of the dataset, p denotes output probability density distribution, Rᵢₙ refers to input dispersion relation graph, α is a regular coefficient, ∥ . . . ∥₂ refers to 12 regularization and w represents weight of the fully connected layers.

In some embodiments, after initializing the respective parameters of the neural network by normal distribution, the training is iteratively performed on the training set by a stochastic gradient descent algorithm.

As an example, these parameters may be initialized by normal distribution with e.g., an average value of 0 and a variance of 0.01 and then are iteratively trained for 2000 rounds on the training set using the Adam random gradient descent algorithm, where each round of training is divided into 1024 samples as a batch for iteration.

In some embodiments, the learning rate of the neural network may be initially set and gradually lowered with the number of trainings.

As an example, the learning rate may be initially set to 0.001 and reduced by ten times every 250 rounds of training. During training, dropout operations and l₂ regularization may be incorporated into the fully connected layers to increase generalization power of the model and avoid over-fitting, wherein the dropout rate for each layer of neuron may be set to 20% and the coefficient α of l₂ regularization may be set to 0.01.

It should be noted that the dispersion relation patterns in the datasets obtained from simulated computation are all theoretical values, and the actual measurement result may deviate from the result of simulated computation to a certain degree. Accordingly, when the neural-network-based prediction model which is trained on the interference-free datasets is applied to measure the critical dimensions of the target to be measured (e.g., grating) corresponding to the non-ideal dispersion relation pattern with interference, the results may greatly deviate from the actual values.

In order to boost robustness of the neural network against various measurement errors that may possibly occur during the measurement, it is of great necessity to enhance the training dataset.

In some embodiments, the dataset may be enhanced by adding various types of random noises to the dispersion relation pattern of the target to be measured obtained from the simulated computation.

As an example, these noises, for example, may be at least one of Gaussian noises, low-frequency disturbances, Perlin noises and Gaussian function type disturbances. For instance, the Gaussian noises (i.e., white noise) may simulate random noises that may occur during the measurement and the random intensity thereof may be in the range from e.g., −0.05 to +0.05. The low-frequency disturbances may simulate floating of the overall intensity signal in the measurement, and the function form may be e.g., A sin (ax+b) with the intensity of the disturbance being randomized e.g., between −0.12 and +0.12, “a” being a random multiple between e.g., 0.5 and 3 multiplied 2π/(the number of pixels on a single side of the dispersion curve), and the initial phase being randomized e.g., between −π and +π. The Gaussian function type disturbance may simulate local intensity deviation in the measurement with the function form following e.g., the following equation (8) as below.

$$A exp ( \frac{{x - μ )}^{2}}{2 {σ}^{2}} ) \qquad ( 8 )$$

A, μ and σ in the equation (8) are all random numbers.

It is discovered in the study that the wavelength (energy) scale and the angular (momentum) scale of the dispersion curve are respectively determined by the spectrometer and Abbe sine condition in the experiment-based measurements. Accordingly, the accuracy of the measurement is guaranteed, but the measured intensity of each point on the dispersion curve may contain errors. Therefore, in some embodiments, the selection for the above types of noises may comply with the following principle: the selected noise type is required to disturb the intensity of the simulated data while not changing peak positions of the dispersion curve as much as possible.

In some embodiments, the dataset may be enhanced by inline enhancement during the training. Accordingly, in these embodiments, the datasets will be enhanced before the input of the simulated dispersion curve to the network, and the above noise disturbances will be added to the clean simulated data.

In some embodiments, the training task of the neural network may be carried out on the computing device 120. Examples of the computing device 120 may include servers. As an example, the server may be equipped with e.g., Intel® Xeon® Gold 6230 Model CPU, 256 GB memory and NVIDIA Tesla V100-PCIE-32 GB graphics.

In some embodiments, the neural network algorithm may be built based on e.g., python 3.6.8 Version, tensorflow-gpu 1.13.1 version or cuda 10.0 version.

In some embodiments, the time for training the neural-network-based prediction model may be set. As an example, the total training time for the neural network may be set to 3 hours.

3. Result Display

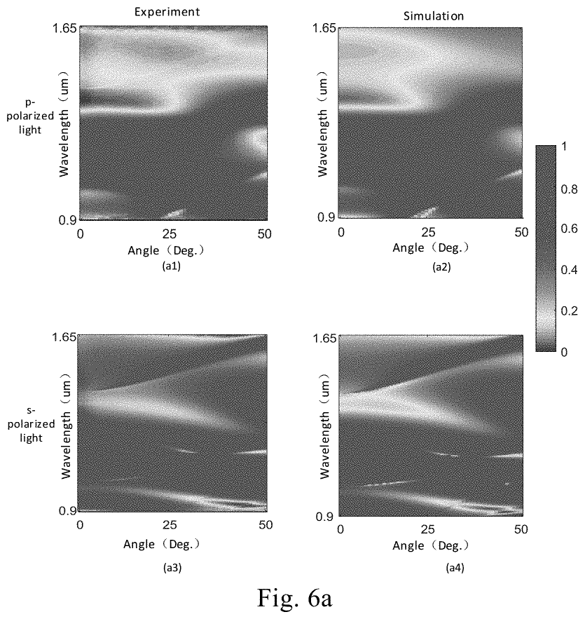

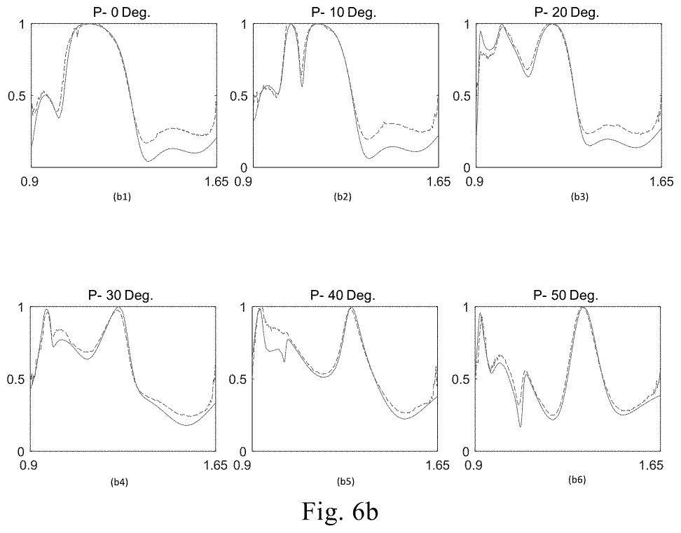

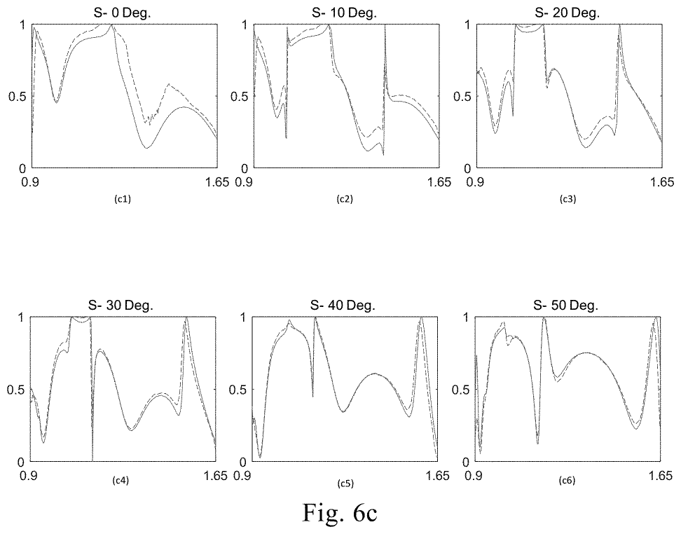

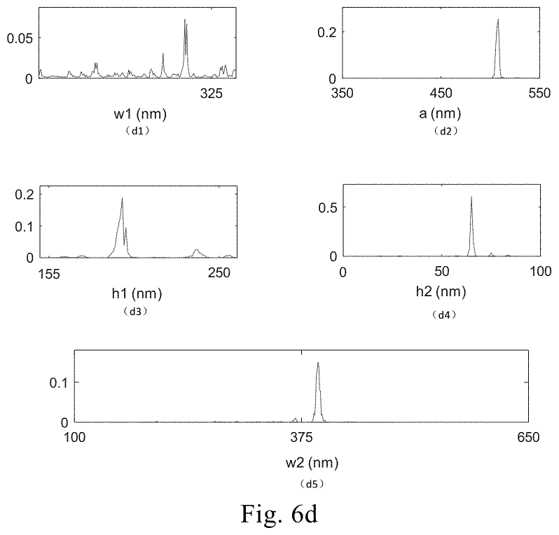

FIGS. 6a to 6d illustrate examples of comparisons between results obtained in accordance with the critical dimension metrology of the present disclosure and experimental results.

In this example, the shape of the modeled geometric topography of the target to be measured (e.g., grating sample) may be modeled into a trapezoidal grating sample having an upper base w1, a lower base w2, a period a, an etching depth h1 and a thickness h2 of silicon layer not etched (see FIG. 1).

In the FIG. 6a, graph a1 and graph a3 respectively illustrate dispersion relation patterns of the target to be measured obtained by the reflective angle-resolved spectrometer during experiments in the case that the p-polarized light and the s-polarized light are incident in kx direction; while graph a2 and graph a4 respectively illustrate the dispersion relation patterns resulted from the simulation by the RCWA simulation algorithm in accordance with the present disclosure in the case of the p-polarized light and the s-polarized light are incident in kx direction. It is observed that the dispersion relation patterns obtained through simulation and the dispersion relation patterns acquired from experiments are remarkably consistent in profile.

To further compare the experimental results with the simulation results in the case that the p-polarized light and the s-polarized light are at different dispersion angles, graphs b1 to b6 of FIG. 6b illustrate a detailed comparison of the spectral lines of the dispersion patterns for the p-polarized light obtained from experiments and simulations in FIG. 6a in the case that each are sliced every 10 degrees (e.g., 0 degree, 10 degrees, 20 degrees, 30 degrees, 40 degrees and 50 degrees) respectively; and graphs c1 to c6 in FIG. 6c illustrate a detailed comparison of the spectral lines of the dispersion patterns for the s-polarized light obtained from experiments and simulations in the case that each are sliced every 10 degrees (e.g., 0 degree, 10 degrees, 20 degrees, 30 degrees, 40 degrees and 50 degrees), respectively; wherein the solid lines represent the simulation results and the dotted lines denote the experimental result. From the experimental and simulation results shown in FIGS. 6b and 6c, it can be seen that the dispersion curves obtained from simulation and the spectral lines acquired from experiments are remarkably consistent at each dispersion angle.

FIG. 6d illustrates measurement results of the five critical dimensions (i.e., upper base w1, lower base w2, period a, etching depth h1 and thickness h2 of silicon layer not etched) output from the neural network of the present disclosure after the processing of the softmax function. The results are interpreted as the probability distribution of the five parameters in a solution space, where the most probable value lies at the position of the maximum value.

It can be seen from FIGS. 6a to 6d that the experimental spectrum and the simulated spectrum are basically consistent. In addition, although they may slightly differ in measurement intensity, the method of the present disclosure may still obtain, through measurement, the critical dimensions of the grating that can enable a satisfactory fitting between the two dispersion curves. One of the advantages of this method is to provide robustness on intensity for experimental measurements.

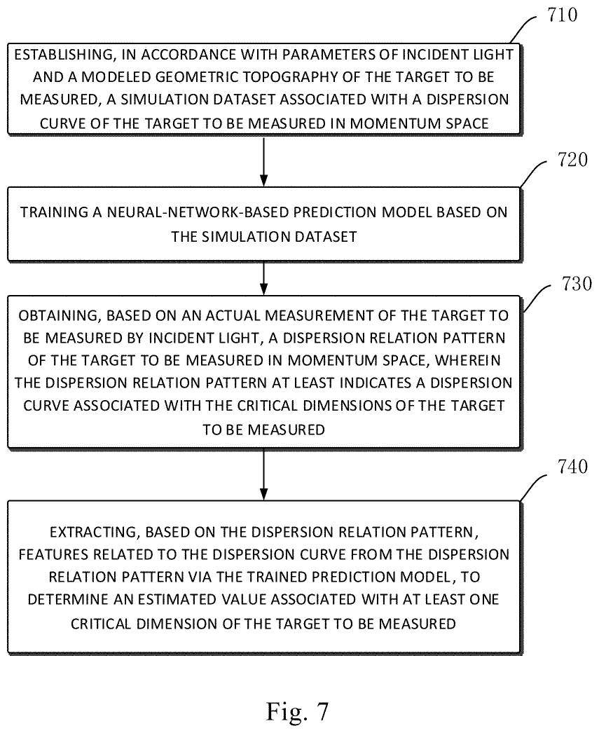

Specific implementations of the method for measuring critical dimensions of the target to be measured in accordance with the present disclosure have been introduced in details above. Next, a flow of method for determining at least one critical dimension of the target to be measured in accordance with one embodiment of the present disclosure is to be depicted with reference to FIG. 7.

At block 710, establishing, in accordance with parameters of incident light and a modeled geometric topography of the target to be measured, a simulation dataset associated with a dispersion curve of a target to be measured in momentum space, wherein the modeled geometric topography is characterized by a plurality of critical dimensions.

In some embodiments, the target to be measured, for example, may be any structure that is suitable to form the dispersion curve or a dispersion relation pattern under the illumination of the incident light. In some other embodiments, the target to be measured may be a periodic structure, and the periodic structure for example is a grating (e.g., an etched grating).

Inventors of the present application have surprisingly recognized that changes of the dispersion curve of the target to be measured in momentum space can reflect critical dimensions of the target to be measured. Accordingly, the critical dimensions of the target to be measured may be estimated based on the dispersion curve of the target to be measured. The inventors further discovered that it is neither economical nor efficient in practice to measure a large amount of samples to be measured to obtain the dispersion relation patterns of the samples in momentum space and further extract the dispersion curves from the dispersion relation patterns. Precision is another issue to be considered. As such, the inventors of the present application propose a method for measuring at least one critical dimensions of the target to be measured by establishing a simulation dataset and using a neural network. According to the above method, the critical dimensions of the target to be measured are measured in a simpler and a more efficient, accurate and economical way.

To obtain a training dataset suitable for a later use of the neural-network-based prediction model, it is required to model the geometric topography of the target to be measured in some embodiments, where the modeled geometric topography may be characterized by a plurality of critical dimensions of the target to be measured.

In an embodiment where the target to be measured, for example, is a periodic structure like a grating, the modeled geometric topography of the grating may be built into a trapezoidal shape, and the critical dimensions may be characterized for example by upper base w1, lower base w2 and height h1 of the trapezoid, period a of the grating, and thickness h2 of the silicon layer etc. Apparently, in other embodiments, the target to be measured may be modeled in other shapes and characterized by different critical dimensions.

The trend of the dispersion curve in momentum space usually reflects the critical dimensions of the target to be measured and may be characterized by a relation between energy (or wavelength) and angle (or momentum).

It is to be noted herein that the conversion between the energy and the wavelength and between the angle and the momentum may be carried out easily via a known formula. Therefore, in momentum space disclosed herein, the energy and the wavelength may be used interchangeably. This also applies to the angle and the momentum.

In some embodiments of the present disclosure, the simulation dataset may be established based on the Rigorous Coupled Wave Analysis (RCWA) algorithm. However, this should not be understood as a limitation. In other embodiments, other suitable algorithms (such as Finite Difference Time Domain (FDTD), Finite Element Method (FEM) and Boundary Element Method (BEM)) and/or combinations thereof may also be utilized to establish the simulation dataset.

In some embodiments, a large amount of simulation datasets may be obtained by altering one or more parameters of the parameters of incident light and the critical dimensions of the modeled geometric topography, wherein the parameters of the incident light, for example, may include incidence angle of incident light, wavelength of incident light and polarization of incident light.

Inventors of the present application further realized that trends or peak positions of the dispersion curves are critical in the dispersion relation patterns measured in practice, and light intensity is an important interference factor. To obtain a dataset that is robust to light intensity, the noises related to the light intensity in some embodiments may be added into at least part of the simulation dataset. Examples of the noises related to the light intensity may include one or more of low-frequency disturbances, Gaussian noises, Perlin noises or Gaussian function type disturbances.

Moreover, due to the limitations of the RCWA algorithm, the simulation dataset may also be corrected via an angular resolution correction and a numerical aperture correction for a measuring objective lens.

At block 720, training a neural-network-based prediction model based on the simulation dataset.

In some embodiments, the neural network may be trained with the enhanced simulation dataset, so as to obtain a prediction model that is robust to light intensity. In some embodiments, the dataset may be enhanced by adding at least one of a Gaussian noise, a low-frequency disturbance, a Perlin noise or a Gaussian function type disturbance to the dispersion relation pattern of the target to be measured for the simulated computation.

In some embodiments, parameters for the neural network including training time and a learning rate etc. may be set.

At block 730, obtaining a dispersion relation pattern of the target to be measured in momentum space based on an actual measurement of the target to be measured by incident light, wherein the dispersion relation pattern at least indicates a dispersion curve associated with the critical dimensions of the target to be measured.

In this step, any metrology devices may be employed as long as they are suitable for obtaining the dispersion relation pattern of the target to be measured. Examples of the metrology devices may include an angle-resolved spectrometer. Furthermore, the angle-resolved spectrometer may be a reflective angle-resolved spectrometer.

In the embodiment utilizing the angle-resolved spectrometer, the dispersion relation pattern of the target to be measured in momentum space may be obtained as pictures by taking photos, wherein the dispersion relation pattern is formed with dispersion curves therein.

In some embodiments, the dispersion relation pattern of the target to be measured in momentum space may be obtained within an angle ranging from −60 to 60 degrees (especially between −60 degrees and 60 degrees) and at a near-infrared band from 900 nm to 1700 nm, or a visible light band from 360 nm to 900 nm, or an ultraviolet band from 200 nm to 360 nm.

It will be appreciated that for the obtained dispersion relation pattern in momentum space, its horizontal coordinate may be measured by energy or wavelength and the vertical coordinate may be measured by angle or momentum.

In some embodiments, the target to be measured may be measured once or more than once in practice, to obtain one or more dispersion relation patterns of the target to be measured in momentum space. The one or more dispersion relation patterns are then input to the trained neural network.

In some embodiments, the target to be measured may be measured in practice by using s-polarized light and p-polarized light respectively, so as to separately obtain an s-polarized dispersion relation pattern and a p-polarized dispersion relation pattern of the target to be measured in momentum space. Afterwards, the s-polarized dispersion relation pattern and the p-polarized dispersion relation pattern are simultaneously input to the prediction model.

In some embodiments, a dispersion curve of the target to be measured in momentum space under the incident light may be obtained based on a dispersion relation pattern of the target to be measured in momentum space, in combination with a dispersion relation pattern of the background of the target to be measured in momentum space and a dispersion relation pattern of a light source of an incident light in momentum space.

At block 740, extracting, based on the dispersion relation pattern, features related to the dispersion curve from the dispersion relation pattern via a trained prediction model, so as to determine an estimated value associated with at least one critical dimension of the target to be measured.

In this step, the dispersion relation pattern obtained at block 730 may be input to the trained neural network.

In some embodiments, features related to the changes (e.g., a trend change and/or peak positions) of the dispersion curves are extracted from the dispersion relation patterns obtained at block 730; and the prediction model may output, based on the features, an estimated probability density distribution of the at least one critical dimension, so as to measure the critical dimensions of the target to be measured.

In some embodiments, the obtained s-polarized dispersion relation pattern and the p-polarized dispersion relation pattern may be simultaneously input to the prediction model, so as to output a more accurate estimated value for the critical dimension.

The flow of an example method for determining at least one critical dimension of the target to be measured has been described above with reference to the drawings. It is to be understood that the above respective steps 710-740 may be implemented by the computing device 120 in the metrology system. In addition, the above example method may have many variants. For example, in some embodiments, a prediction model on the basis of the neural network may have already been trained for estimating or determining the key parameters. Therefore, in these embodiments, the method for determining critical dimensions of the target to be measured, may not include steps of such as provision of simulation dataset and/or training a neural-network-based prediction model according to the simulation dataset.

Therefore, in these embodiments, a method for determining critical dimensions of the target to be measured may include steps of: obtaining a dispersion relation pattern of the target to be measured in momentum space, wherein the dispersion relation pattern is generated in momentum space via a spectrum apparatus after an incident light illuminates the target to be measured and at least indicates a dispersion curve related to critical dimensions of the target to be measured; extracting features related to the dispersion curve from the dispersion relation pattern via a neural-network-based prediction model based on the dispersion relation pattern, wherein the prediction model has been trained with a sample dataset; and determining, based on extracted features related to the dispersion curve, an estimated value associated with the critical dimension of the target to be measured.

In further embodiments, the sample dataset may be a simulation dataset established on the basis of both parameters of incident light and a modeled geometric topography of the target to be measured, where the modeled geometric topography is characterized by a plurality of critical dimensions of a target to be measured.

In some other embodiments, the neural-network-based prediction model may be trained on the basis of experimental dataset measured in practice.

In some other embodiments, the neural-network-based prediction model may be trained on the basis of a combination of experimental dataset measured in practice and the above simulation dataset.

The exemplary method for determining at least one critical dimension of the target to be measured in accordance with one embodiment of the present disclosure has been described above. It is to be understood that the method disclosed herein may be particularly applied to the manufacturing procedure of the semiconductor chips and also may measure the manufacturing structure inline. In particular, as compared to the technical solutions using light spectrum and a library search in the prior art, the method of the present disclosure calculates the critical dimensions by using the dispersion relation patterns or dispersion curves in momentum space (instead of spectrum) and the neural network (instead of a library search). Consequently, the proposed solution in the present disclosure is more accurate and efficient. Furthermore, it is noted that since pictures contain much more information than the spectrum, the traditional library search can hardly be applied to the dispersion relation patterns in the form of images or pictures.

In addition to the above method, the present disclosure also relates to a measurement system or metrology system, which may include: a spectrometer for measuring the target to be measured to generate a dispersion relation pattern, and a computing device configured to operatively perform (or enable the measurement system or apparatus to perform) the above described method steps. In some embodiments, the spectrometer may include the angle-resolved spectrometer described above.

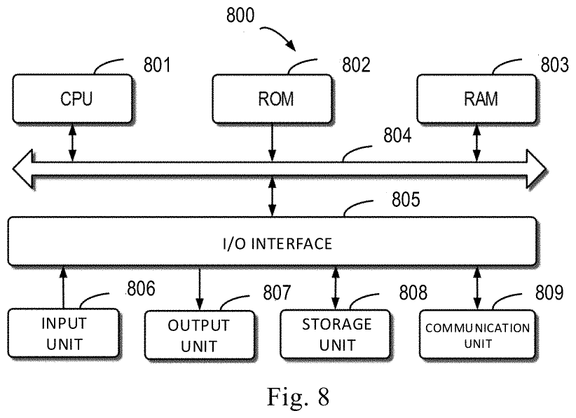

Moreover, the present disclosure may also relate to a non-transient machine-readable storage medium having machine-readable program instructions stored thereon, which is configured to enable an apparatus or the aforementioned measurement system or metrology system to perform the above method. FIG. 8 schematically illustrates a block diagram of an electronic device 800 for implementing embodiments of the present disclosure. The device 800 may be a device for implementing the method 700 as shown in FIG. 7. As shown in FIG. 8, the device 800 comprises a central process unit (CPU) 801, which can execute various suitable actions and processing based on the computer program instructions stored in the read-only memory (ROM) 802 or computer program instructions loaded in the random-access memory (RAM) 803. The RAM 803 can also store all kinds of programs and data required by the operation of the device 800. CPU 801, ROM 802 and RAM 803 are connected to each other via a bus 804. The input/output (I/O) interface 805 is also connected to the bus 804.

A plurality of components in the device 800 is connected to the I/O interface 805, including: an input unit 806, an output unit 807, and a storage unit 808. The above described method and processing, such as method 700, can be executed by the processing unit 801. For example, in some embodiments, the method 700 can be implemented as a computer software program stored in the machine-readable medium, e.g., storage unit 808. In some embodiments, the computer program can be partially or fully loaded and/or mounted to the apparatus 800 via ROM 802 and/or communication unit 809. When the computer program is loaded to RAM 803 and executed by CPU 801, one or more operations of the above described method can be implemented. Alternatively, in other embodiments, CPU 801 may be configured via any other suitable ways (e.g., by means of firmware) to execute one or more actions of the method 700.

It is to be further explained that the present disclosure can relate to a method, apparatus, system and/or computer program product. The computer program product can include a computer-readable storage medium, on which the computer-readable program instructions for executing various aspects of the present disclosure can be loaded.

The computer-readable storage medium can be a tangible apparatus that maintains and stores instructions utilized by the instruction executing apparatuses. The computer-readable storage medium can be, but not limited to, such as electrical storage device, magnetic storage device, optical storage device, electromagnetic storage device, semiconductor storage device or any appropriate combinations of the above. More concrete examples of the computer-readable storage medium (non-exhaustive list) include: portable computer disk, hard disk, random-access memory (RAM), read-only memory (ROM), erasable programmable read-only memory (EPROM or flash), static random-access memory (SRAM), portable compact disk read-only memory (CD-ROM), digital versatile disk (DVD), memory stick, floppy disk, mechanical coding devices, punched card stored with instructions thereon, or a projection in a slot, and any appropriate combinations of the above. The computer-readable storage medium utilized here is not interpreted as transient signals per se, such as radio waves or freely propagated electromagnetic waves, electromagnetic waves propagated via waveguide or other transmission media (such as optical pulses via fiber-optic cables), or electric signals propagated via electric wires.

The described computer-readable program instruction can be downloaded from the computer-readable storage medium to each computing/processing device, or to an external computer or external storage via Internet, local area network, wide area network and/or wireless network. The network can comprise copper-transmitted cable, optical fiber transmission, wireless transmission, router, firewall, switch, network gate computer and/or edge server. The network adapter card or network interface in each computing/processing device receives computer-readable program instructions from the network and forwards the computer-readable program instructions for storage in the computer-readable storage medium of each computing/processing device.

The computer program instructions for executing operations of the present disclosure can be assembly instructions, instructions of instruction set architecture (ISA), machine instructions, machine-related instructions, microcodes, firmware instructions, state setting data, or source codes or target codes written in any combinations of one or more programming languages, wherein the programming languages comprise object-oriented programming languages, e.g., Smalltalk, C++ and so on, and traditional procedural programming languages, such as “C” language or similar programming languages. The computer-readable program instructions can be implemented fully on the user computer, partially on the user computer, as an independent software package, partially on the user computer and partially on the remote computer, or completely on the remote computer or server. In the case where remote computer is involved, the remote computer can be connected to the user computer via any type of networks, including local area network (LAN) and wide area network (WAN), or to the external computer (e.g., connected via Internet using the Internet service provider). In some embodiments, state information of the computer-readable program instructions is used to customize an electronic circuit, e.g., programmable logic circuit, field programmable gate array (FPGA) or programmable logic array (PLA). The electronic circuit can execute computer-readable program instructions to implement various aspects of the present disclosure.

Various aspects of the present disclosure are described here with reference to flow chart and/or block diagram of a method, device (system) and computer program product(s) according to embodiments of the present disclosure. It should be understood that each block of the flow chart and/or block diagram and the combination of various blocks in the flow chart and/or block diagram can be implemented by computer-readable program instructions.

The computer-readable program instructions can be provided to processor of a voice interaction apparatus, or processing unit of general-purpose computer, dedicated computer or other programmable data processing apparatuses to manufacture a machine, such that the instructions that, when executed by the processor of the computer or other programmable data processing apparatuses, generate means for implementing functions/actions stipulated in one or more blocks in the flow chart and/or block diagram. The computer-readable program instructions can also be stored in the computer-readable storage medium and cause the computer, programmable data processing apparatus and/or other devices to work in a particular manner, such that the computer-readable medium stored with instructions comprises an article of manufacture, including instructions for implementing various aspects of the functions/actions stipulated in one or more blocks of the flow chart and/or block diagram.

The computer-readable program instructions can also be loaded into computer, other programmable data processing apparatuses or other devices, so as to execute a series of operation steps on the computer, other programmable data processing apparatuses or other devices to generate a computer-implemented procedure. Therefore, the instructions executed on the computer, other programmable data processing apparatuses or other devices implement functions/actions stipulated in one or more blocks of the flow chart and/or block diagram.

The flow chart and block diagram in the drawings illustrate system architecture, functions and operations that may be implemented by a device, method and computer program product according to multiple implementations of the present disclosure. In this regard, each block in the flow chart or block diagram can represent a module, a part of program segment or code, wherein the module and the part of program segment or code include one or more executable instructions for performing stipulated logic functions. In some alternative implementations, it should be noted that the functions indicated in the block can also take place in an order different from the one indicated in the drawings. For example, two successive blocks can be in fact executed in parallel or sometimes in a reverse order dependent on the involved functions. It should also be noted that each block in the block diagram and/or flow chart and combinations of the blocks in the block diagram and/or flow chart can be implemented by a hardware-based system exclusive for executing stipulated functions or actions, or by a combination of dedicated hardware and computer instructions.

Furthermore, it is to be appreciated that the above described flow is just an example. Although the steps of the method are described in a particular order in the description, it is not required or suggested that these operations must be executed according to the particular order, or the expected results can be achieved only when all illustrated operations are performed. Conversely, the depicted steps may be executed in different orders. Additionally or alternatively, some steps may be omitted or a plurality of steps may be combined into one step for execution, and/or one step may be decomposed into a plurality of steps to be performed.

Although the present invention has been described in details in the drawings and above description, the explanations and descriptions should be considered as illustrative or exemplary, rather than being restrictive. The present invention is not limited to the embodiments disclosed herein. When practicing the claimed invention, those skilled in the art may understand and further apply other variants of the disclosed embodiments by studying drawings, disclosure and the attached claims.

In the claims, the term “comprise/include” does not exclude other elements, and the indefinite article “one” or “a/an” does not exclude the plural form. A single element or other units may fulfill the function of a plurality of items described in the claims. Although some features are only disclosed in embodiments different from each other or dependent claims, their combinations may also be advantageously utilized. Without deviating from the spirit and scope of the present application, any possible combinations of the respective features disclosed in various embodiments or dependent claims are within the protection scope of the present application.

Furthermore, any reference signs in the claims should not be construed as limitations to the scope of the present invention.

1. A metrology method for determining critical dimensions of a target to be measured, comprising:
establishing, in accordance with parameters of incident light and a modeled geometric topography of the target to be measured, a simulation dataset associated with a dispersion curve of the target to be measured in momentum space, wherein the modeled geometric topography is characterized by a plurality of critical dimensions;
training a neural-network-based prediction model based on the simulation dataset;
obtaining, based on an actual measurement of the target to be measured by incident light, a dispersion relation pattern of the target to be measured in momentum space, wherein the dispersion relation pattern at least indicates a dispersion curve associated with the critical dimensions of the target to be measured; and
extracting, based on the dispersion relation pattern obtained from the actual measurement as an input, features related to the dispersion curve from the dispersion relation pattern via the trained prediction model, to determine an estimated value associated with at least one critical dimension of the target to be measured.

2. The metrology method according to claim 1, wherein the extracting features related to the dispersion curve from the dispersion relation pattern via the trained prediction model, to determine an estimated value associated with at least one critical dimension of the target to be measured includes:
outputting via the prediction model an estimated probability density distribution of the at least one critical dimension.

3. The metrology method according to claim 1, wherein obtaining, based on the actual measurements of the target to be measured by incident light, the dispersion relation pattern of the target to be measured in momentum space includes:
measuring the target to be measured in practice with at least one of s-polarized light and p-polarized light, to obtain at least one of the corresponding s-polarized and p-polarized dispersion relation patterns of the target to be measured in momentum space.

4. The metrology method according to claim 3, wherein extracting features related to the dispersion curve from the dispersion relation pattern via the trained prediction model, to determine an estimated value associated with at least one critical dimension of the target to be measured includes:
obtaining both the s-polarized and p-polarized dispersion relation patterns and outputting both of them to the prediction model, to acquire the estimated value associated with at least one critical dimension of the target to be measured.

5. The metrology method according to claim 1, wherein obtaining the simulation dataset includes obtaining the simulation dataset by altering at least one of:
incidence angle of incident light;
wavelength of incident light;
polarization of incident light; and
critical dimensions of the modeled geometric topography.

6. The metrology method according to claim 1, further comprising:
adding noises related to light intensity into at least a part of the simulation dataset, to obtain an enhanced simulation dataset with robustness to light intensity; and
training the prediction model based on the enhanced simulation dataset.

7. The metrology method according to claim 6, wherein the noises related to light intensity includes one or more of a low-frequency disturbance, a Gaussian noise, a Perlin noise or a Gaussian function type disturbance.

8. The metrology method according to claim 1, wherein obtaining, based on the actual measurements of the target to be measured by incident light, the dispersion relation pattern of the target to be measured in momentum space includes:
measuring the target to be measured in practice with an angle-resolved spectrometer to obtain the dispersion relation pattern of the target to be measured in momentum space, wherein the angle-resolved spectrometer has a measurement angle selected from a range from −60 to 60 degrees and a measuring wavelength selected from a near-infrared band from 900 nm to 1700 nm, or a visible light band from 360 nm to 900 nm, or an ultraviolet band from 200 nm to 360 nm.

9. The metrology method according to claim 1, wherein obtaining the dispersion relation pattern of the target to be measured in momentum space includes:
obtaining the dispersion relation pattern of the target to be measured in momentum space under the incident light on the basis of a dispersion relation pattern of the background of the target to be measured in momentum space and a dispersion relation pattern of a light source of the incident light in momentum space.

10. The metrology method according to claim 1, wherein both the dispersion curve and the dispersion relation pattern are defined by a first coordinate and a second coordinate, wherein the first coordinate denotes energy or wavelength and the second coordinate denotes angle or momentum.

11. The metrology method according to claim 1, wherein obtaining the simulation dataset includes:
establishing the simulation dataset based on at least one of Rigorous Coupled Wave Analysis (RCWA) algorithm, Finite Difference Time Domain (FDTD), Finite Element Method (FEM) and Boundary Element Method (BEM).

12. The metrology method according to claim 11, further comprising:
correcting the simulation dataset via at least one of a numerical aperture correction and an angular resolution correction for an objective lens for measurement.

13. The metrology method according to claim 11, wherein the neural network includes a convolutional neural network.

14. A metrology method for determining critical dimensions of a target to be measured, comprising:
obtaining, based on an actual measurement, a dispersion relation pattern of the target to be measured in momentum space, wherein the dispersion relation pattern is generated in momentum space via a spectrum apparatus after the target to be measured is illuminated by incident light and the dispersion relation pattern at least indicates a dispersion curve related to critical dimensions of the target to be measured;
extracting, based on the dispersion relation pattern as an input, features related to the dispersion curve from the dispersion relation pattern via a neural-network-based prediction model, where the prediction model has been trained with a sample dataset; and
determining, based on extracted features related to the dispersion curve, an estimated value associated with at least one critical dimension of the target to be measured.

15. The metrology method according to claim 14, wherein the sample dataset is a simulation dataset established on the basis of parameters of incident light and a modeled geometric topography of the target to be measured, wherein the modeled geometric topography is characterized by a plurality of critical dimensions of a target to be measured.

16. A metrology system, comprising:
a spectrometer configured to generate, based on an actual measurement of the target to be measured by incident light, a dispersion relation pattern of a target to be measured in momentum space, where the dispersion relation pattern at least indicates a dispersion curve related to critical dimensions of the target to be measured; and
a computing device configured to operatively execute the metrology method according to claim 1.

17. (canceled)

18. A non-transient machine-readable storage medium with machine-readable program instructions stored thereon, which are configured to enable a metrology apparatus to perform steps of the metrology method according to claim 1.
